(19) United States
(12) Patent Application Publication
(10) Pub. No.: US 2025/0349358 A1
(43) Pub. Date: Nov. 13, 2025

(54) ASSOCIATIVE PROCESSING CELL WITH XNOR+XOR FUNCTIONS

(71) Applicant: GSI Technology, Inc., Sunnyvale, CA (US)

(72) Inventors: Lee-Lean Shu, Sunnyvale, CA (US); Bob Haig, Sunnyvale, CA (US)

(21) Appl. No.: 19/199,980

(22) Filed: May 6, 2025

Related U.S. Application Data
(60) Provisional application No. 63/644,409, filed on May 8, 2024.

(51) Int. Cl. G11C 15/04

(52) U.S. Cl. CPC G11C 15/04

(57) ABSTRACT

A memory array may include a read bit line (RBL), a complimentary read bit line (RBLb), a plurality of storage cells each selectably coupled to the RBL and the RBLb such that an XNOR of a read enable (RE) signal and a content of the respective storage cell is output to the RBL in response to the RE signal and an XOR of the RE signal and the content of the respective storage cell is output to the RBLb in response to the RE signal, and a sensing circuit coupled to the RBL and the RBLb and configured to compare a signal on the RBL to a signal on the RBLb and output a comparison result.

### RELATED APPLICATIONS

This application claims priority to U.S. Provisional Application No. 63/644,409, filed May 8, 2024 and entitled “Associative Processing Cell with XNOR+XOR Functions,” the entirety of which is incorporated by reference herein.

### FIELD

This disclosure relates generally to a static random access memory cell that may be used for computations.

### BACKGROUND

An array of memory cells, such as dynamic random access memory (DRAM) cells, static random access memory (SRAM) cells, content addressable memory (CAM) cells or non-volatile memory cells, is a well-known mechanism used in various computer or processor based devices to store digital bits of data. The various computer and processor based devices may include computer systems, smartphone devices, consumer electronic products, televisions, internet switches and routers and the like. The array of memory cells are typically packaged in an integrated circuit or may be packaged within an integrated circuit that also has a processing device within the integrated circuit. The different types of typical memory cells have different capabilities and characteristics that distinguish each type of memory cell. For example, DRAM cells take longer to access, lose their data contents unless periodically refreshed, but are relatively cheap to manufacture due to the simple structure of each DRAM cell. SRAM cells, on the other hand, have faster access times, do not lose their data content unless power is removed from the SRAM cell and are relatively more expensive since each SRAM cell is more complicated than a DRAM cell. CAM cells have a unique function of being able to address content easily within the cells and are more expensive to manufacture since each CAM cell requires more circuitry to achieve the content addressing functionality.

Various computation devices that may be used to perform computations on digital, binary data are also well-known. The computation devices may include a microprocessor, a CPU, a microcontroller and the like. These computation devices are typically manufactured on an integrated circuit, but may also be manufactured on an integrated circuit that also has some amount of memory integrated onto the integrated circuit. In these known integrated circuits with a computation device and memory, the computation device performs the computation of the digital binary data bits while the memory is used to store various digital binary data including, for example, the instructions being executed by the computation device and the data being operated on by the computation device.

More recently, devices have been introduced that use memory arrays or storage cells to perform computation operations. In some of these devices, a processor array to perform computations may be formed from memory cells. These devices may be known as in-memory computational devices.

Big data operations are data processing operations in which a large amount of data must be processed. Machine learning uses artificial intelligence algorithms to analyze data and typically requires a lot of data to perform. The big data operations and machine learning also are typically very computationally intensive applications that often encounter input/output issues due to a bandwidth bottleneck between the computational device and the memory that stores the data. The above in-memory computational devices may be used, for example, for these big data operations and machine learning applications since the in-memory computational devices perform the computations within the memory thereby eliminating the bandwidth bottleneck.

Deep learning (DL) has recently changed the development of intelligent systems and is widely adopted in many real-life applications. There is a high demand for DL processing in different computationally limited and energy-constrained devices. Binary Neural Networks (BNN) can be used in such devices and/or other applications to increase deep learning capabilities. BNN can be implemented and embedded on size restricted devices and save a significant amount of storage, computation cost, and energy consumption. However, BNN applications generally require tradeoffs among extra memory, computation cost, and higher performance. This article provides a complete overview of recent developments in BNN. Some BNN systems use 1-bit activations and weights in 1-bit convolution networks.

### BRIEF DESCRIPTIONS OF THE DRAWINGS

FIG. 1 shows an example BNN operation according to some embodiments of the disclosure.

FIGS. 2A, 2B, 3A, and 3B show example BNN output results according to some embodiments of the disclosure.

FIGS. 4A, 4B, 5A, and 5B show example BNN with bias output results according to some embodiments of the disclosure.

FIG. 6 shows an example circuit diagram of an XNOR+XOR cell read port according to some embodiments of the disclosure.

FIG. 7 shows an example truth table of an XNOR+XOR cell read port according to some embodiments of the disclosure.

FIG. 8 shows an example circuit diagram of an XNOR+XOR memory cell and write port according to some embodiments of the disclosure.

FIG. 9 shows an example truth table of an XNOR+XOR cell write port according to some embodiments of the disclosure.

FIG. 10 shows an example circuit diagram of an XNOR+XOR cell read port according to some embodiments of the disclosure.

FIG. 11 shows an example circuit diagram of a processing array according to some embodiments of the disclosure.

FIG. 12 shows an example circuit diagram of a sense amplifier according to some embodiments of the disclosure.

FIG. 13 shows an example circuit diagram of an XNOR+XOR cell read port according to some embodiments of the disclosure.

### DETAILED DESCRIPTION OF SEVERAL EMBODIMENTS

Systems and methods described herein can implement the computation requirements for BNN with 1 bit activation and 1 bit weight in a fast and efficient manner. BNN may use XNOR and popcount operations to compute outputs. Systems and methods described herein can combine the XNOR and popcount operations into a single memory cycle in an associative processing array.

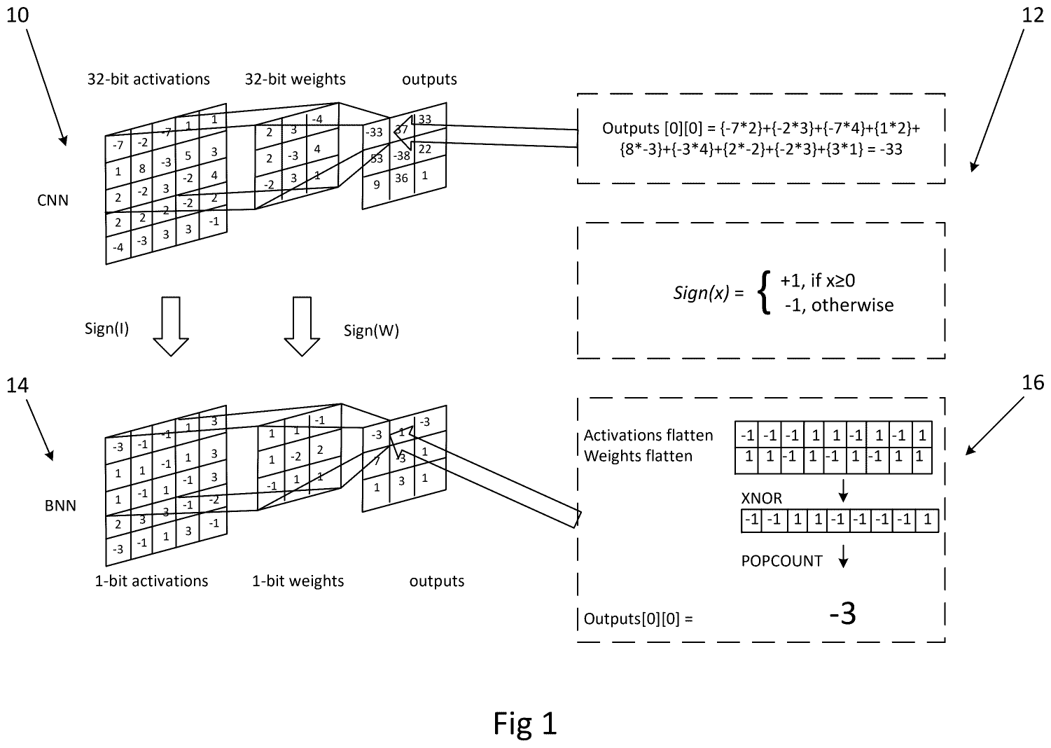

FIG. 1 shows an example BNN operation according to some embodiments of the disclosure. FIG. 1 maps a convolutional neural network (CNN) 10 operation 12 onto a BNN 14 operation 16. Operations 12, 16 may be equivalent in result, but the results may be obtained differently due to the respectively different structures of CNN 10 and BNN 14.

CNN 10 can have 32-bit activations and 32-bit weights, and the weights and activations may be input into a multiply accumulation (MAC) operation 12. In the MAC operation 12, the 32-bit activation matrix and the 32 bit weight matrix can be multiplied and added, with a result of Sign(x)=+1 if x>=0 and Sign(x) =−1 otherwise.

However, with models becoming larger, it may be desirable to increase speed and reduce storage requirements. While legacy MAC operations may be 32 bit floating point operations, the resolution may be dropped to a lower bit level. This can simplify operation at the cost of accuracy. To regain accuracy, more layers may be added. At the extreme end, this can result in a binary configuration with one bit and many layers. With a binary configuration, or a BNN 14, there may be no need to do the multiplication and addition. Instead, using XOR and XNOR can give the result. That is, in MAC operation 16, an XOR operation and XNOR operation may be performed, and the results may be added. If the result of addition is more than zero, the output may be considered as a 1, if the result of addition is less than zero, the output may be considered as a 0.

BNN 14 of FIG. 1 has, as an example, a 3×3 convolution layer with both activation and weight represented by 1 bit with the value of (+1, −1). In this representation, the mantissa is 1 and the sign bit is either 1 for +1 or 0 for −1. The output of matrix multiplication and accumulation of 2 3×3 matrix of BNN is the popcount result of 9 XNOR operations. The output is 1 if the popcount result is >=0. The output is 0 if the popcount result is <0.

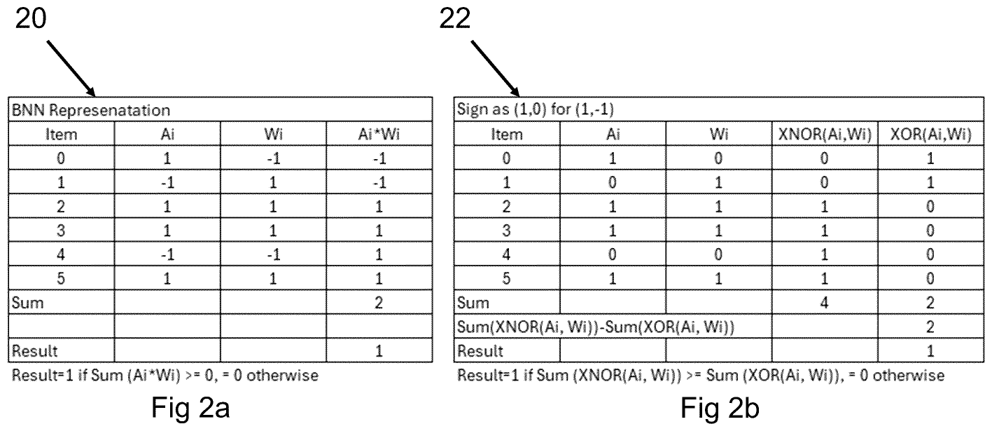

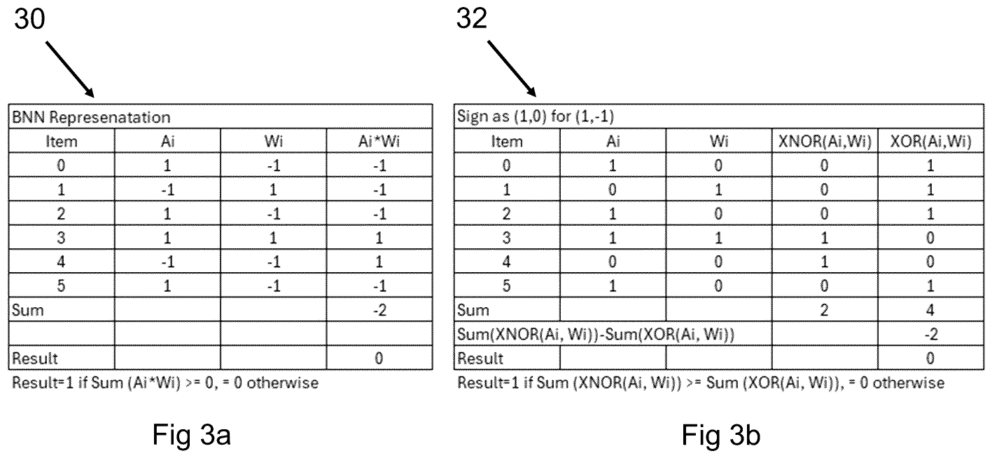

FIGS. 2A, 2B, 3A, and 3B show example BNN output results according to some embodiments of the disclosure. In each chart, A is activation and W is weight, and each example includes six items. In the BNN representations 20, 30, A and W are multiplied for each item, and the products are added to one another to get the sum. In FIG. 2A, the sum obtained in BNN representation 20 is 2, which gives a result of binary 1. In FIG. 3A, the sum obtained in BNN representation 30 is −2, which gives a result of binary 0.

In these examples, there are six items. Multiplying A and W and adding results together yields the sum. BNN representation 22 of FIG. 2B and BNN representation 32 of FIG. 3B are variations where the values of A and W can be 1 or 0. The difference between BNN representation 20 and BNN representation 22, and the difference between BNN representation 30 and BNN representation 32, is that there is no −1 in BNN representation 22 or BNN representation 32. In BNN representation 22 or BNN representation 32, the −1 is replaced by 0. To get the same results as BNN representations 20, 30 of FIGS. 2A and 3A, XNOR and XOR of the A and W values may be obtained, and XOR may be subtracted from XNOR.

BNN representation 20 of FIG. 2A is an example of 6 items' BNN representation of Ai and Wi. If Sum (Ai* Wi)>=0, the output result is 1, otherwise it is 0. The output result Y can be expressed as follows:

Y=1*−1+−1*1+1*1+1*1+−1*−1+1*1=−1+−1+1+1+1+1=2=>Result=1 if Y>=0

BNN representation 22 of FIG. 2B is a binary equivalent to BNN representation 20 of FIG. 2A where Ai and Wi are represented by (1,0) (in place of (1, −1) in FIG. 2A). If XNOR and XOR functions are performed on every item, and the sums of XNOR and XOR are compared, it can be seen whether the sum of XNOR is the same or larger than the sum of XOR. If the sum of XNOR is the same or larger than the sum of XOR, then the result is 1.

BNN representation 30 of FIG. 3A is an example where 4 items of Ai*Wi are −1 and 2 items of Ai*Wi are 1 to yield the final sum of −2 for the result of 0. BNN representation 32 of FIG. 3B is a binary equivalent to BNN representation 30 of FIG. 3A where there are 4 items of XOR=1 and 2 items of XNOR=1 to yield the result of 0, matching to the sum of Ai*Wi in FIG. 3A.

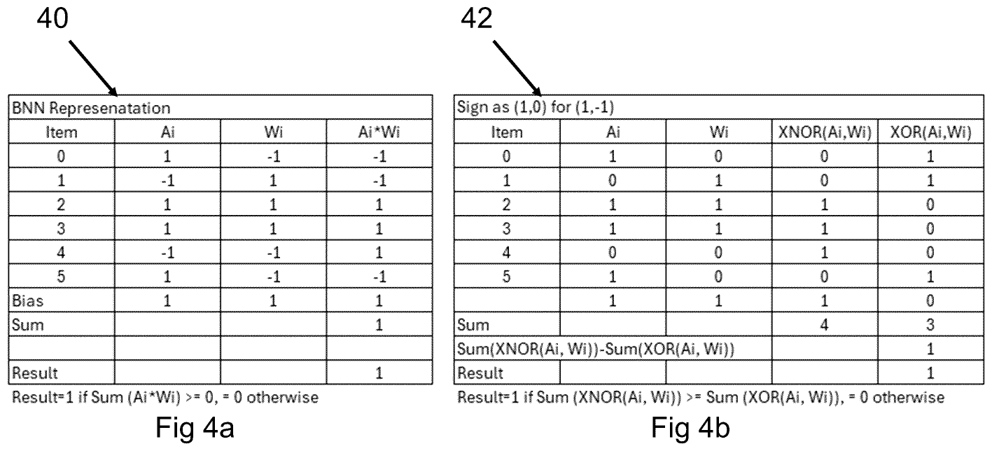

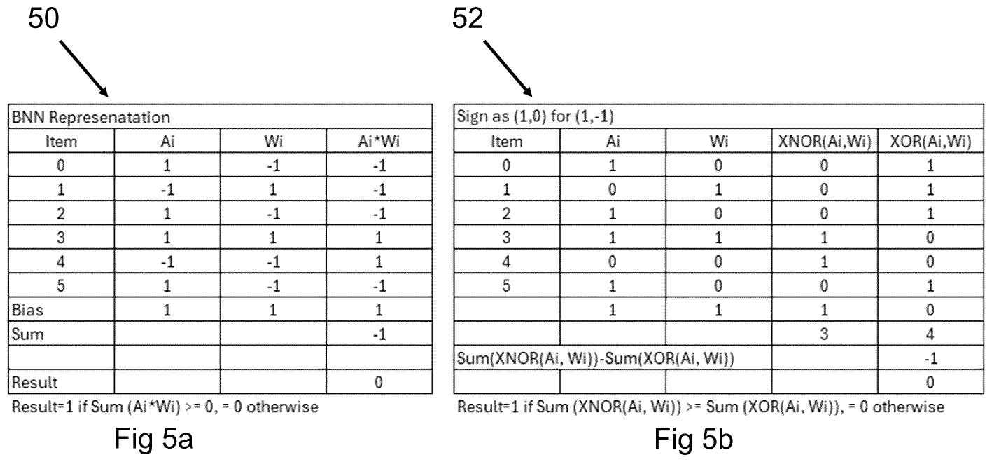

FIGS. 4A, 4B, 5A, and 5B show example BNN with bias output results according to some embodiments of the disclosure. These examples are similar to those of FIGS. 2A-3B except there is a bias. Specifically, in FIGS. 2A-3B, the difference is either more than 0 or less than 0 (the case where Sum (Ai*Wi)>0 or <0). However, if there are an even number of items, it is possible to arrive at a sum of 0. That is, for the case of Sum(Ai*Wi)=0, there may be a need for a bias such that Result=1 if Sum (Ai*Wi)=0.

BNN representations 40, 42, 50, 52 address this issue by including a bias of 1 that is added to the sum (e.g., a fixed bias with Ai=1, Wi=1). In BNN representation 40, for example, the sum is 0. By adding a bias of 1 to the multiplication results, the final sum is 1, and therefore the final result can be given as 1. BNN representation 42 is the XNOR-XOR binary equivalent of BNN representation 40. In BNN representation 42, there is a fixed bias of Ai=1, Wi=1 to have an extra XNOR (Ai, Wi)=1 so that the result is 1 if Sum (XNOR(Ai, Wi))=Sum(XOR(Ai,Wi)).

In BNN representation 50, the sum remains negative even with the added bias of 1, and therefore the final result can be given as 0. In this example, Sum(Ai*Wi)=−2 before the bias. With the bias, the result is reduced to −1, maintaining the correct result. BNN representation 52 is the XNOR-XOR binary equivalent of BNN representation 50. In the binary representation, Sum(XNOR(Ai,Wi))<Sum(XOR(Ai,Wi)) to yield the result=0, after consideration of bias. The bias may be required if the number of items is even to enable a correct outcome when half of Ai*Wi=−1 and the other half of Ai*Wi=1, yielding the result of 0 before the bias. However, if the number of items is odd, then the bias may not be needed, because the numbers of −1 and 1 are always not equal.

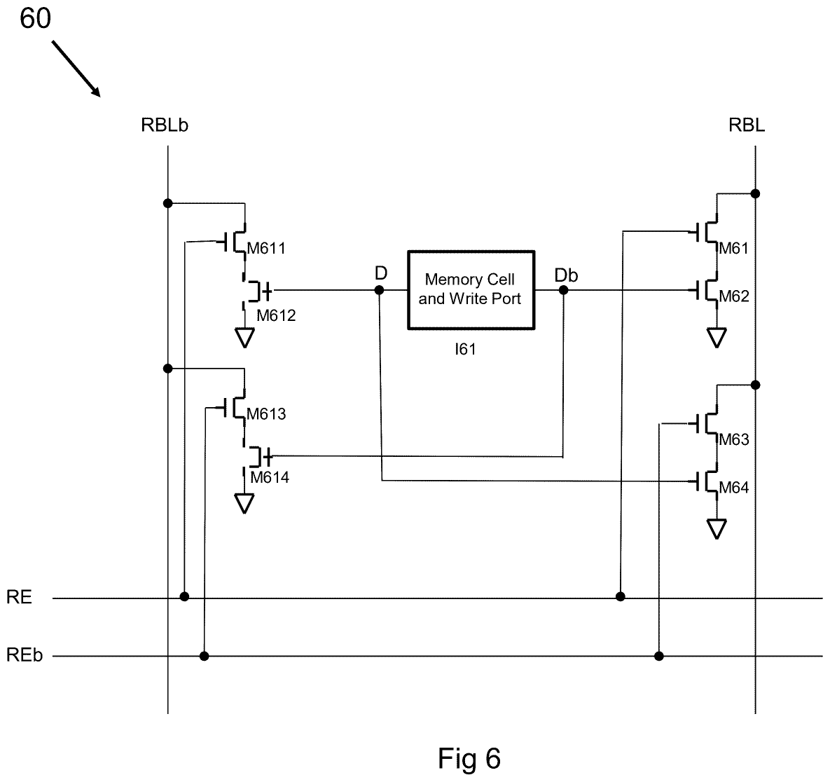

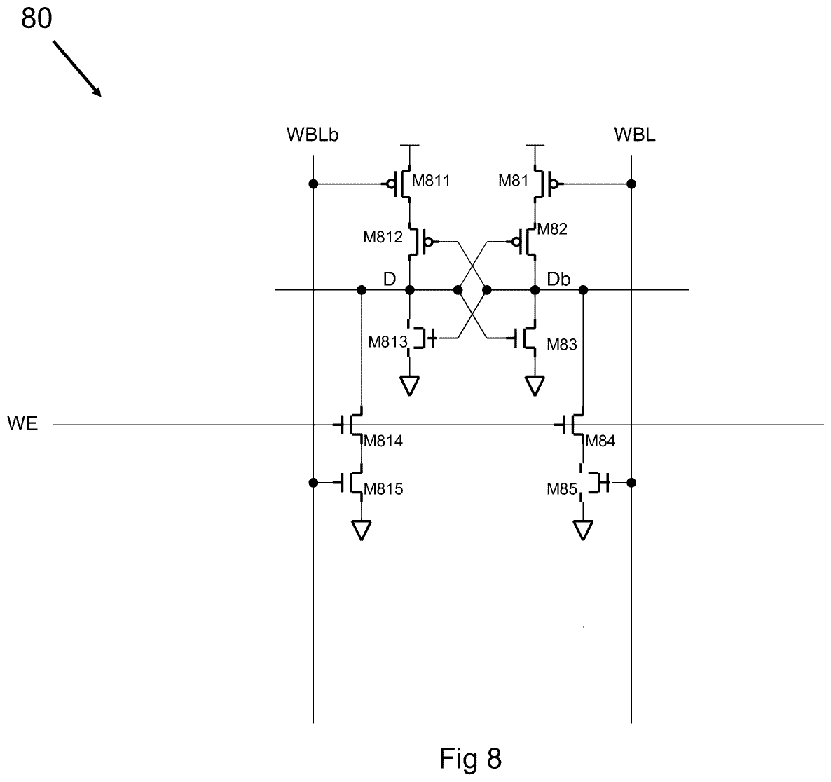

FIG. 6 shows an example circuit diagram of an XNOR+XOR cell read port 60 according to some embodiments of the disclosure. Memory cell 161 may be an associative memory cell and write port, for example. In some embodiments, memory cell 161 can be a 6T SRAM cell. In some embodiments, memory cell 161 can be the circuit described in detail below with reference to FIG. 8. In some embodiments, memory cell 161 may have a different configuration altogether. In any case, memory cell 161 may generate storage node D and complementary storage node Db, where Db is the inverse of D. Read bit line RBL may be one read port of memory cell 161, and complementary read bit line RBLb may be another read port of memory cell 161. Read word line RE may be a read word line of memory cell 161, and complementary read word line REb may be the complementary, or differential, read word line of memory cell 161. Storage node D and complementary storage node Db may be coupled to read bit line RBL and complementary read bit line RBLb through a plurality of switches M61, M62, M63, M64, M611, M612, M613, M614 as shown. For example, switches M61, M62, M63, M64, M611, M612, M613, M614 may be MOSFET devices or any other switching device. Switches M61, M62, M63, M64, M611, M612, M613, M614 may be activated by read enable RE and complimentary read enable REb, where REb is the inverse of RE.

In the example of FIG. 6, if the cell is XNOR, RBL will be 1 and RBLb will be 0. If the cell is XOR, RBL will be 0 and RBLb will be 1. A weight may be stored in memory cell 161. Activation may come in on RE and REb. In a precharge cycle, RE and REb may be 0, so memory cell 161 may be inactive. If RE=1 and D=1, memory cell 161 may function as an XNOR cell, M61 may turn on, and M62 may not turn on. If RE=1 and REb=0, then M63 may be off, providing a tri-state condition. Looking at the other side, if RE=1, M611 may turn on, D=1, and RBLb may be pulled down to 0.

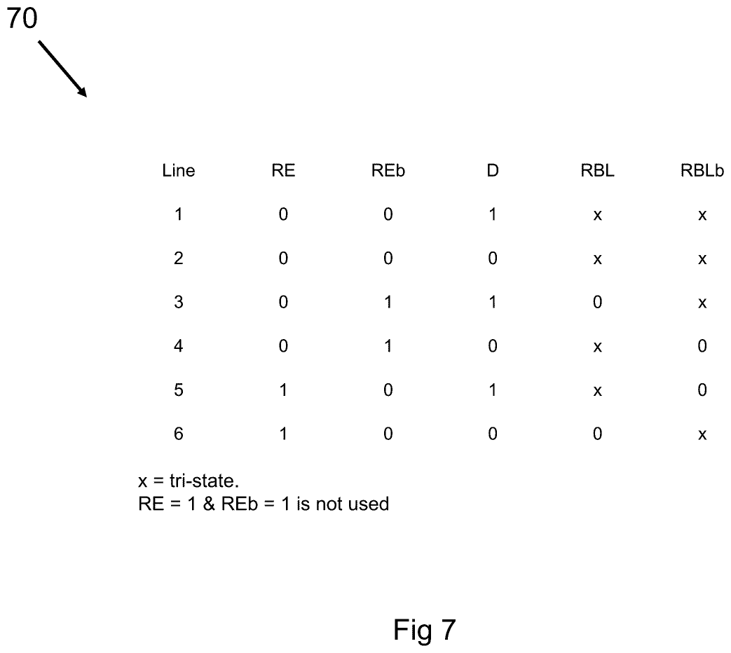

FIG. 7 shows an example truth table 70 of the XNOR+XOR cell read port 60 of FIG. 6 according to some embodiments of the disclosure. Truth table 70 shows the state of RBL and RBLb for each combination of conditions for RE, REb, and D.

If RE=REb=0, then M61, M63, M611, and M613 may be off, and RBL and RBLb are not driven by memory cell 161, no matter the status of D and Db. In this case, RBL and RBLb may be in pre-charged state or may be driven by other memory cells on each line. Line 1 and 2 of truth table 70 show the status of this condition.

If RE=0 and REb=1, then M63 and M613 may be on, and M61 and M611 may be off. RBL may be pulled down by M64 if D=1, and RBLb may be pulled down by M614 if Db=1 (D=0). RBL is not driven if D is 0 and M64 is off, and RBLb is not driven if Db=0 (D=1) and M614 is off. Line 3 and 4 of truth table 70 show the status of this condition.

If RE=1 and REb=0, then M61 and M611 may be on, and M63 and M613 may be off. RBL may be pulled down by M62 if Db=1 (D=0), and RBLb may be pulled down by M612 if D=1. RBL is not driven if Db=0 (D=1) and M62 is off. RBLb is not driven if D=0 and M612 is off. Line 5 and 6 of truth table 70 show the status of this condition.

For the active memory cells in the active cycle, REb is always the complementary of RE. RBL and RBLb status are shown in lines 3-6 of truth table 70. If x is considered as 1, where x is when RBL and RBLb are not driven by the memory cell, then RBL and RBL can be expressed by the following equations:

RBL=OR (AND (RE, D), AND (REb, Db))=XNOR (RE, D) EQ1

RBLb=OR (AND (RE, Db), AND (REb, D))=XOR (RE, D) EQ2

For the non-active memory cells in the active cycle, RE=REb=0, then RBL and RBLb are not driven by those cells as shown in the truth table 70 in line 1 and 2 as x. In the pre-charged cycle or standby cycle where the memory cells are not active, RE=REb=0, the cells are not driven, and have shown in truth table 70 in line 1 and 2 as x. RE=1 and REb=1 condition makes RBL=RBLb=0 and is not used in the example embodiments.

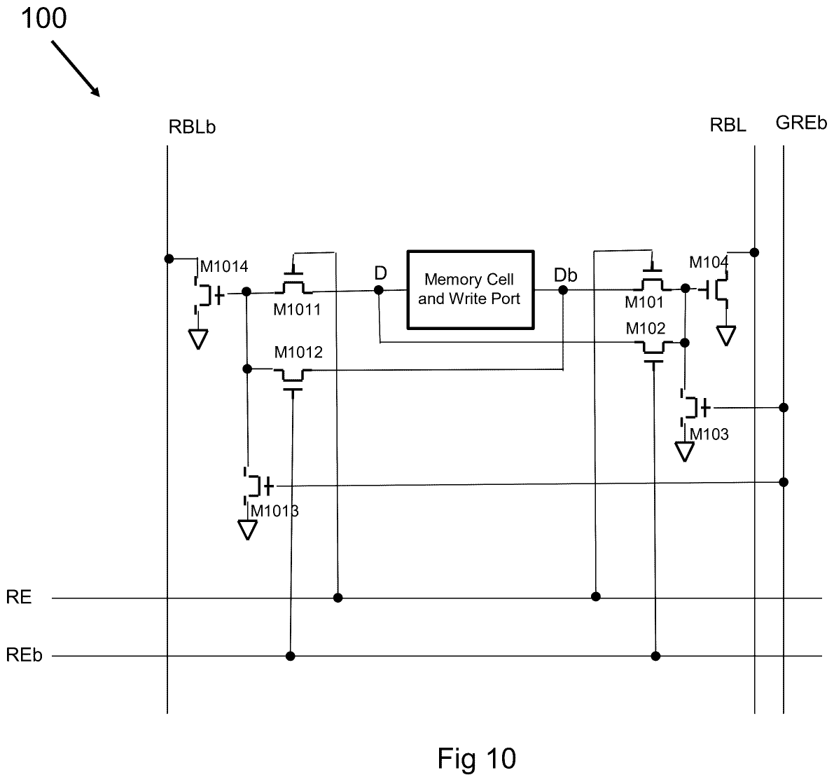

In the example of FIG. 6, when RE is turned on, M61 is on and M62 is off, and RBL will see capacitance from having the two transistors in series. A similar condition will be seen on RBLb from M613 being on and M614 being off. An example of a circuit that can address this issue is shown and described below with reference to FIG. 10.

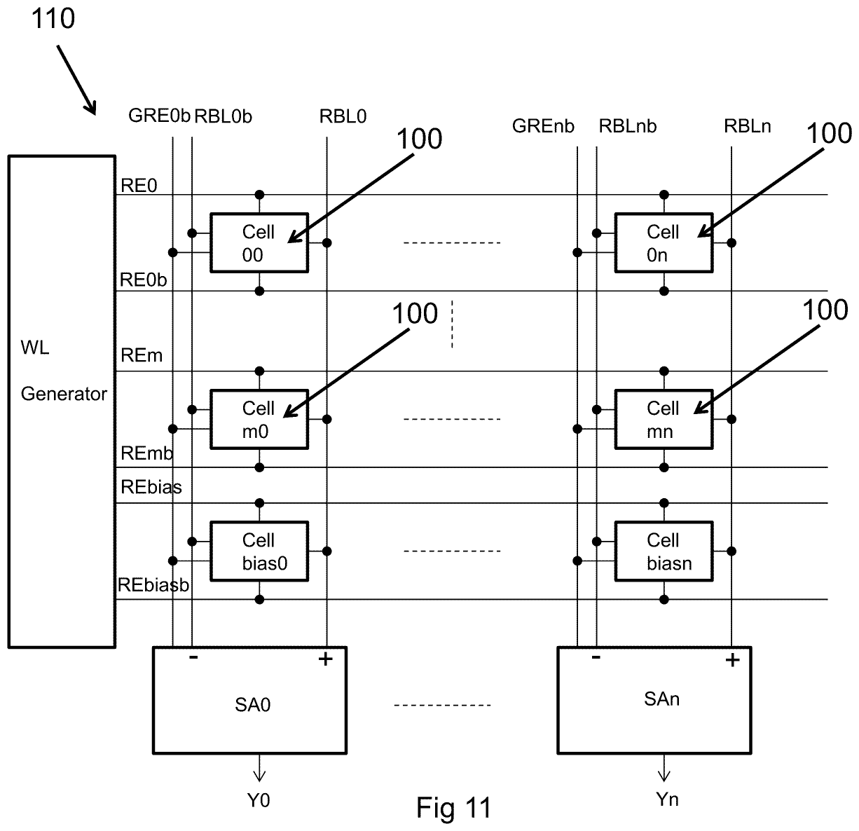

FIG. 8 shows an example circuit diagram of an XNOR+XOR memory cell and write port 80 according to some embodiments of the disclosure. This example is one possible embodiment of memory cell 161 of FIG. 6 and/or of the memory cell(s) of FIGS. 10, 11, and/or 13 which are described in detail below.

This example is a dual port SRAM cell that may be used for computation, including the XNOR+XOR computation performed herein. The dual port SRAM cell may include two cross coupled inverters (transistors M813, M812 may pair as one inverter and transistors M83 and M82 may pair as another inverter) that may form a latch or storage cell and access transistors M811, M814, M815, M81, M84, M85 that may be coupled together as shown in FIG. 6 to form an SRAM cell. The SRAM cell may be operated as a storage latch and may have a read port and a write port so that the SRAM cell is a dual port SRAM cell. The two inverters may be cross coupled since the input of the first inverter is connected to the output of the second inverter and the output of the first inverter is coupled to the input of the second inverter as shown in FIG. 6.

Write word line WE, write bit line WBL, and complementary write bit line WBLb may be coupled to the SRAM cell. For example, WE may be coupled to the gate of each of the two access transistors M814, M84 that are part of the SRAM cell. The write bit line and its complement (WBL and WBLb) may each be coupled to a gate of the respective access transistors M811, M815, M81, M85 as shown in FIG. 6. The source of each of transistors M813, M815, M83, M85 may be coupled to ground. The drain of each of those access transistors may be coupled to each side of the cross coupled inverters (labeled D and Db in FIG. 6). The dual port SRAM cell may write data into the dual port SRAM cell by addressing/activating the dual port SRAM cell using a signal on the write word line (WE) and then writing data into the dual port SRAM cell using the write bit lines (WBL, WBLb).

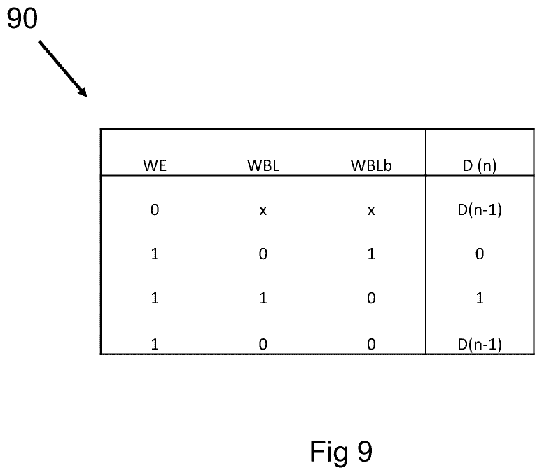

FIG. 9 shows an example truth table 90 of XNOR+XOR cell write port 80 of FIG. 8 according to some embodiments of the disclosure. In the truth table, D(n) is storage data on the current write cycle, and D(n-1) is storage data before the current write cycle.

Referring back to FIGS. 4B and 5B, Wi can be stored in a memory cell as D in FIG. 6, Ai can be read word line as RE in FIG. 6, and REb as the complementary Read Word Line of RE in FIG. 6. This may yield the following relationships:

RBL=XNOR (RE, D)=XNOR (Ai, Wi) EQ3

RBLb=XOR (RE, D)=XOR (Ai, Wi) EQ4

FIG. 10 shows an example circuit diagram of an XNOR+XOR cell read port 100 according to some embodiments of the disclosure. This example embodiment addresses the issue present in the circuit of FIG. 6 where there is capacitance on RBL due to the series transistors. In XNOR+XOR cell read port 100, there is a single transistor M104 driving RBL and a single transistor M1014 driving RBLb. M104 and M1014 may be matching transistors so the pull down values are the same on either side. The XNOR and/or XOR function can be implemented one stage before the connection to RBL and/or RBLb, where RE can drive transistor(s) M101 to get Db and M1011 to get D, and REb can drive transistor(s) M102 to get D and 1012 to get Db. This will form the XOR and XNOR function. Because only one respective driver transistor M104, M1014 is coupled to RBL and RBLb, RBL and RBLb will not see capacitance from other transistors.

In the embodiment of FIG. 10, the states of RBL and RBLb may be the same as the truth table in FIG. 7 and EQ3 and EQ4. However, only one transistor M104 drives RBL and one transistor M1014 drives RBLb, compared to two driver transistors for each of RBL and

RBLb in FIG. 6, resulting in less parasitic capacitance on RBL and RBLb for the FIG. 10 circuit than the FIG. 6 circuit. Specifically, in FIG. 6, RBL=x when RE=1 and Db=0, M61 is on and is a parasitic gated capacitance to RBL. In FIG. 10, there is no such parasitic capacitance. However, M101, M102, M1011, M1012 may be low VT transistor to avoid RE and REb having higher voltage levels than D and Db to drive full voltage in the memory cell without VT voltage loss to the gates of M104 and M1014. Also, the embodiment of FIG. 10 may include additional pre-charge transistors M103 and M1013 to pre-charge the gate of RBL and RBLb driver transistors M104 and M1014 to 0 such that M104 and M1014 are off in an active cycle on non-active cells. In summary, in this embodiment, RBL=NOT(RE*Db+REb*D)=XNOR (RE,D), and RBLb=NOT (RE*D+REb*Db)=XOR (RE,D).

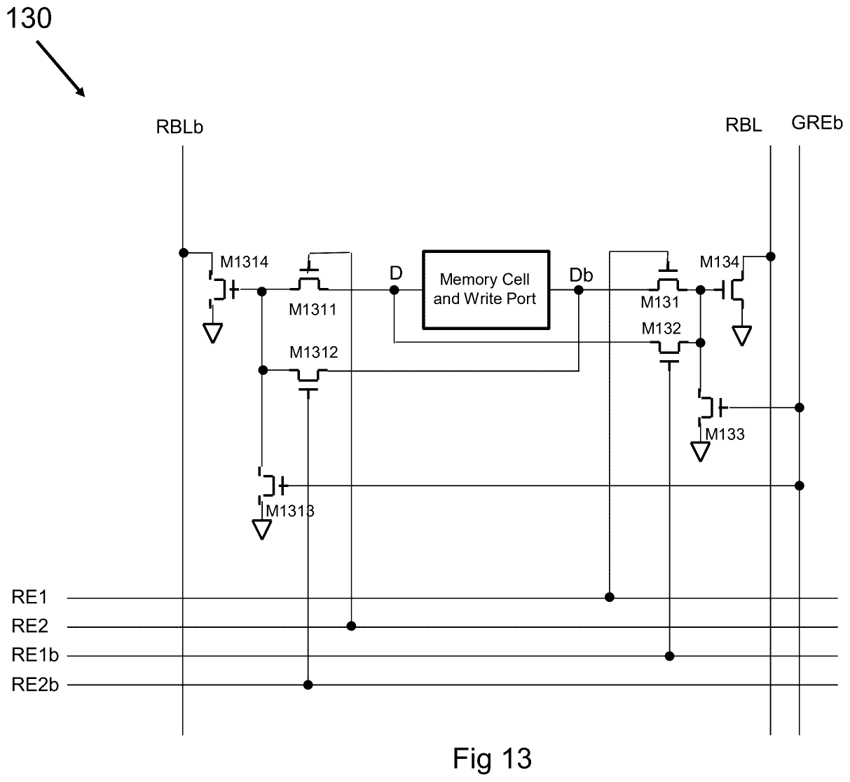

FIG. 11 shows an example circuit diagram of a processing array 110, including a plurality of cells 100 of FIG. 10, according to some embodiments of the disclosure. While cells 100 of FIG. 10 are shown in this example, it should be understood that cells 60 of FIG. 6 and/or cells 130 of FIG. 13, or other similar circuits with XNOR+XOR functionality, may be substituted for cells 100 of FIG. 10 in other embodiments.

In processing array 110, each cell, such as cell 00, . . . , cell On and cell m0, . . . , cell mn, is the cell shown in FIG. 10. The cells may form an array of cells laid out as shown in FIG. 11. Processing array 110 may perform computations using the computational capabilities of the dual port SRAM cell described above, including the XNOR+XOR computations described herein. In addition to the cells, processing array 110 may include a bias (Cell bias0, . . . , Cell bias n), which can be a full cell or can be a pull down. Processing array 110 may be formed by M word lines (such as RE0, RE0b, . . . , REm, REmb) and N bit lines (such as RBL0, RBL0b, . . . , RBLn, RBLnb). Processing array 110 may also include a word line generator (WL Generator) that may generate word line signals as well as a plurality of sense amplifiers (such as SA0, . . . , SAn) that may perform read operations using the bit lines. Processing array 110 may be manufactured on an integrated circuit or may be integrated into another integrated circuit depending on the use of processing array 110.

In a read cycle, WL generator may generate one or multiple RE signals in a cycle to turn on/activate one or more cells. As described herein, the RBL and RBLb lines of the cells activated by the RE signal may form XNOR or XOR functions whose output is sent to a respective sense amplifier SA. The sense amplifier may compare the voltages on RBL and RBLb and output a logic 1 or logic 0 depending on whether RBL or RBLb is higher.

For example, depending on how many cells output XOR and how many cells output XNOR, there will be some value pulled down on RBL and some value pulled down on RBLb, respectively. SA can compare RBL and RBLb and determine which side is pulled down more, indicating which operation is dominant. If RBLb is lower, it may indicate an XNOR function. If RBL is lower, it may indicate an XOR function. Accordingly, through one bit line, processing array 110 can perform a MAC operation. This may be contrasted with a 16 bit MAC circuit with much more overhead than processing array 110 having a single bit line.

For example, in FIG. 11, when an active cell on RBL/RBLb exhibits XNOR (REi, Di) function, there is no pull down on RBL, but pull down by M1014 of circuit 100 in FIG. 10 on RBLb. If an active cell on RBL/RBLb exhibits XOR (REi, Di) function, then M104 is on to pull down RBL. In other words, the equivalent resistor R_M104 of M104 is connected RBL to VSS if an active cell exhibits XOR (REi, Di) function, and the equivalent resistor R_M1104 of M1104 is connected RBLb to VSS if an active cell exhibits XNOR (REi, Di) function. R_M104 and R_M1104 of all cells may be matched in transistor performance, so the resistor values are matched, R_M104i=R_M1104j, i,j=all cells in a column. So, in RBL/RBLb column in circuit 110 of FIG. 11, if there are m number of XNOR (REi, Di) cells, then RBLb is connected to VSS through R_M1014/m; if there are n number of XOR (REi, Di) cells, then RBL is connected to VSS through R_M104/n. By sensing the resistor values of RBL and RBLb, it can be determined which type of XNOR (REi, Di) or XOR (REi, Di) cells are more active in the column. If more cells are XNOR (REi, Di) than XOR (REi, Di), or m>n, then R_M104/n>R_M1014/m and RBL voltage level is higher than RBLb voltage level. Through SAj, the result Yj=1 by sensing the differential volage of RBL and RBLb. Similarly, if more cells are XOR (REi, Di) than XNOR (REi, Di), then Yj=0. In FIG. 11, RBL, RBLb and SA output Y can be expressed as follows:

RBL=Sum (XNOR (REi, Di)=Sum (XNOR (Ai, Wi)) EQ5

RBLb=Sum (XOR (REi, Di))=Sum (XOR (Ai, Wi)) EQ6

Yj=1 if RBL>RBLb, =0 if RBL<RBLb EQ7

i=0 to k, k<=m EQ8

j=0 to n EQ9

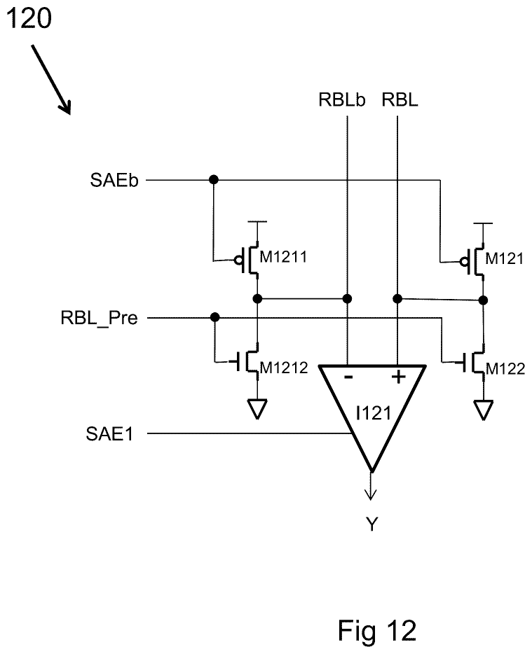

FIG. 12 shows an example circuit diagram of a sense amplifier 120 according to some embodiments of the disclosure. Sense amplifier 120 is an example that may be used as SA in circuit 110 of FIG. 11, but it should be understood that other sense amplifier designs may be used, as long as they are capable of comparing RBL and RBLb and determining which side is pulling down more.

In this example, M122 and M1212 may be pre-charge transistors to pre-charge RBL and RBLb to VSS in a pre-charge phase. M121 and M1211 may behave as resistors against the driver transistors of the memory cells during the sensing. In the active phase, RBL_Pre may go from high to low so that RBL and RBLb are at floating low. REi and REib of active cells may be active when GREb goes from high to low and SAEb goes from high to low to enable M121 and M1211 as pull up resistors. RBL and RBLb voltage levels may be given as the ratio of M121 and M1211 against M104 in cells 100, where RB=XNOR (REi,Di), and against M1014 in cells 100 where RBLb=XOR (REi,Di), respectively. This may be stated as follows:

V_RBL=VDD*R_M104/n/(R_M104/n+R_M121) EQ10

V_RBLb=VDD*R_M1104/m/(R_M1104/m+R_M1211) EQ11

Where R_M121 is the turn on resistor of M121, R_M1211 is the turn on resistor of M1211, m is the number of cells exhibit XNOR (REi,Di), n is the number of cells exhibit XOR (REi,Di) R_M104 are the resistors of M104 of active cells, in circuit 100 of FIG. 11 where the cells exhibit XNOR (REi,Di) R_M1014 are the resistors of M104 of active cells, in circuit 100 of FIG. 11 where the cells exhibit XOR (REi,Di) R_M104 and R_M1014 of all cells 100 in circuit 110 are all matched, R_M121 is matched to R_M1211, and all Ri_M121 and Ri_M1211 are matched, then VRBL has higher voltage than VRBLb if m>n, and SA output Y=1 when SAE1 is active to activate SA 1121.

In other words, SA output is 1 when the number of XNOR (REi, Di) cells are more than the number of XOR (REi, Di) cells, otherwise it is 0. This is also shown in EQ7.

Once SA output Y result is stabilized and is latched to the next stage, the active phase may be completed, and the cycle is turned to pre-charge phase. SAE1 can go low to disable SA, RE and REb can go low to turn off the cell, SAEb can go high to turn off M121 and M1211, and RBL_Pre and GREb can then go up to pre-charge RBL, RBLb and memory cells to a pre-charge state.

Returning to FIG. 11, there is one row in circuit 110 for the bias cell. For a bias cell (rather than a simple pull down), Di in the bias cell may be stored as 1, and when the active cells are even number, REbias=1 and REbiasb-0 in the active cycle may give a 1 cell bias, or extra XNOR (REbias, Dbias) to favor RBL. This makes Y=1 when the number of XNOR (REi, DI) is equal to XOR (REi, Di). If the active cells are an odd number, bias cells may be inactive, REbias=REbiasb=0. The bias cell described here maybe a normal cell like FIG. 10; or it may simply be a pull-down transistor gated by REbiasb on RBLb, if the pull-down transistor is matched to the RBL/RBLb driver transistors of a normal cell.

The active cells in a column can be from 1 to M. If the number of active cells is less than M, non-active cells RE and REb may be 0 in the active cycle, their drivers on RBL and RBLb may be off, and they will not affect the result of the active operation.

Each column of circuit 110 in FIG. 11 may perform M number of a Ai*Wi and sum it together for BNN operation in a cycle, or the popcount result of Sum (A0*W0, A1*W1, . . . , AM*WM). The array of n columns in circuit 110 may perform n popcount results of M-element BNN operations in a single circle.

FIG. 13 shows an example circuit diagram of an XNOR+XOR cell read port 130 according to some embodiments of the disclosure. The example circuit 130 is one in which more bit lines than are necessary to perform the MAC operation are present. Additional bit lines may be present to allow for additional equations beyond XOR and XNOR, which may be applicable to uses cases other than the disclosed MAC operations, for example. Even though circuit 130 includes additional bit lines, it may be configured to operate in the same manner as the other embodiments described herein.

For example, in FIG. 13, RE and REb are split into two ports, where RE1/RE1b form the XNOR function on RBL and RE2/RE2b form the XOR function on RBLb. That is, RE1 and RE2 may be driven to the same value, and RE1b and RE2b may be driven to the same value. Circuit 130 may be used in the same way as circuit 100 in FIG. 10 when RE1=RE2 and RE1b=RE2b. As in FIG. 10, M31, M32, M311, M312 may be low VT devices. Accordingly, RBL=NOT (RE1*Db+RE1b*D=XNOR (RE1,D), and RBLb=NOT (RE2*D+RE2b*Db)=XOR (RE2,D). Circuit 130 may also be used with different configurations wherein RBL and RBLb may have their own single ended SA. In this manner, there may be more Boolean functions possible on the bit line, such as the following:

When RE1=1, RE1b=0, RBL=AND (D0, D1, . . . , Di) EQ12

When RE1=0, RE1b=1, RBL=AND (D0b, D1b, . . . , Dib)=NOR (D0, D1, . . . , Di) EQ13

When RE2=1, RE2b=0, RBLb=AND (D0b, D1b, . . . , Dib)=NOR (D0, D1, . . . , Di) EQ14

When RE2=0, RE2b=1, RBLb=AND (D0, D1, . . . , Di) EQ15

In summary, the embodiments described herein may provide one or more of the following features.

In some embodiments described above, a memory array may comprise a read bit line (RBL), a complimentary read bit line (RBLb), a plurality of storage cells each selectably coupled to the RBL and the RBLb, a plurality of first coupling circuits, each respective first coupling circuit coupling a respective storage cell of the plurality of storage cells to the RBL such that an XNOR of a read enable (RE) signal and a content of the respective storage cell is output to the RBL in response to the RE signal, a plurality of second coupling circuits, each respective second coupling circuit coupling a respective storage cell of the plurality of storage cells to the RBLb such that an XOR of the RE signal and the content of the respective storage cell is output to the RBLb in response to the RE signal, and a sensing circuit coupled to the RBL and the RBLb and configured to compare a signal on the RBL to a signal on the RBLb and output a comparison result. Some embodiments may comprise a bias coupled to the RBL and the RBLb. In some embodiments, the comparison result may represent a multiply-accumulate result of contents of the plurality of storage cells. In some embodiments, each of the plurality of first coupling circuits may be configured to pull down the RBLb in response to the XNOR.

In some embodiments, each of the plurality of first coupling circuits may comprise a first switch pair comprising a first switch configured to close in response to the RE signal being high and a second switch configured to close in response to a complimentary data signal from the respective storage cell being high, the first switch pair being arranged to couple RBL to ground by closing the first switch and the second switch, and a second switch pair comprising a third switch configured to close in response to a complimentary RE signal being high and a fourth switch configured to close in response to a data signal from the respective storage cell being high, the second switch pair being arranged to couple RBL to ground by closing the third switch and the fourth switch. In some embodiments, the first switch may selectably couple the respective storage cell to the second switch, the second switch may selectably couple RBL to ground, the third switch may selectably couple the respective storage cell to the fourth switch, and the fourth switch may selectably couple RBL to ground.

In some embodiments, each of the plurality of second coupling circuits may be configured to pull down the RBL in response to the XOR. In some embodiments, each of the plurality of second coupling circuits may comprise a third switch pair comprising a fifth switch configured to close in response to the RE signal being high and a sixth switch configured to close in response to a data signal from the respective storage cell being high, the third switch pair being arranged to couple RBLb to ground by closing the fifth switch and the sixth switch, and a fourth switch pair comprising a seventh switch configured to close in response to a complimentary RE signal being high and an eighth switch configured to close in response to a complimentary data signal from the respective storage cell being high, the fourth switch pair being arranged to couple RBLb to ground by closing the seventh switch and the eighth switch. In some embodiments, the fifth switch may selectably couple the respective storage cell to the sixth switch, the sixth switch may selectably couple RBLb to ground, the seventh switch may selectably couple the respective storage cell to the eighth switch, and the eighth switch may selectably couple RBLb to ground.

In some embodiments described above, a memory array may comprise a read bit line (RBL), a complimentary read bit line (RBLb), a plurality of storage cells each selectably coupled to the RBL and the RBLb such that an XNOR of a read enable (RE) signal and a content of the respective storage cell is output to the RBL in response to the RE signal and an XOR of the RE signal and the content of the respective storage cell is output to the RBLb in response to the RE signal, and a sensing circuit coupled to the RBL and the RBLb and configured to compare a signal on the RBL to a signal on the RBLb and output a comparison result. Some embodiments may comprise a bias coupled to the RBL and the RBLb. In some embodiments, the comparison result may represent a multiply-accumulate result of contents of the plurality of storage cells. Some embodiments may comprise a plurality of first coupling circuits coupled to respective ones of the plurality of storage cells, each of the plurality of first coupling circuits being configured to pull down the RBL in response to the XOR of the respective one of the plurality of storage cells. Some embodiments may comprise a plurality of second coupling circuits coupled to respective ones of the plurality of storage cells, each of the plurality of second coupling circuits being configured to pull down the RBLb in response to the XNOR of the respective one of the plurality of storage cells.

In some embodiments described above, a method may comprise supplying a read enable signal to a memory array comprising a plurality of storage cells each selectively coupled to a read bit line (RBL) and a complimentary read bit line (RBLb), in response to the read enable signal, outputting, by each respective storage cell, a respective XNOR of the read enable signal and a respective content of the respective storage cell to the RBL, thereby forming an RBL signal, in response to the read enable signal, outputting, by each respective storage cell, a respective XOR of the read enable signal and a respective content of the respective storage cell to the RBLb, thereby forming an RBLb signal, sensing, by a sensing circuit, the RBL signal on the RBL and the RBLb signal on the RBLb, comparing, by the sensing circuit, the RBL signal and the RBLb signal, and outputting a result of the comparing. Some embodiments may comprise supplying a bias to the RBL and the RBLb. In some embodiments, the result of the comparing may represent a multiply-accumulate result of contents of the plurality of storage cells. In some embodiments, the outputting the respective XNOR may comprise pulling down the RBLb in response to the respective XNOR. In some embodiments, the outputting the respective XOR may comprise pulling down the RBL in response to the respective XOR.

In some embodiments described above, a memory computation cell may comprise a storage cell configured to store data (D) and complementary data (Db), a read word line (RE), a complementary read word line (REb), and a read bit line (RBL). The RBL may be coupled to at least two of D, Db, RE, and REb. The RBL may be configured to output an XNOR function between RE and D. The memory computation cell may further comprise a complementary read bit line (RBLb) coupled to at least two of D, Db, RE, and REb. The RBLb may be configured to output an XOR function between RE and D.

In some embodiments, the RBL may be coupled by a first coupling circuit comprising a first switch pair comprising a first switch configured to close in response to RE being high and a second switch configured to close in response to REb being high, the first switch pair being arranged to couple RBL to ground by closing the first switch or the second switch; and a second switch pair comprising a third switch configured to close in response to REb being high and a fourth switch configured to close in response to RE being high, the second switch pair being arranged to couple RBLb to ground by closing the third switch or the fourth switch. In some embodiments, the first switch pair may selectably couple the storage cell to a switch that selectably couples RBL to ground and the second switch pair may selectably couple the storage cell to a switch that couples RBLb to ground. In some embodiments, the RBL may be coupled by a second coupling circuit comprising a third switch pair comprising a fifth switch configured to close in response to RE being high and a sixth switch configured to close in response to D being high, the third switch pair being arranged to couple RBLb to ground by closing the fifth switch and the sixth switch; and a fourth switch pair comprising a seventh switch configured to close in response to REb being high and an eighth switch configured to close in response to Db being high, the fourth switch pair being arranged to couple RBLb to ground by closing the seventh switch and the eighth switch. In some embodiments, the fifth switch may selectably couple the storage cell to the sixth switch, the sixth switch may selectably couple RBLb to ground, the seventh switch may selectably couple the storage cell to the eighth switch, and the eighth switch may selectably couple RBLb to ground.

The foregoing description, for purpose of explanation, has been described with reference to specific embodiments. However, the illustrative discussions above are not intended to be exhaustive or to limit the disclosure to the precise forms disclosed. Many modifications and variations are possible in view of the above teachings. The embodiments were chosen and described in order to best explain the principles of the disclosure and its practical applications, to thereby enable others skilled in the art to best utilize the disclosure and various embodiments with various modifications as are suited to the particular use contemplated.

The system and method disclosed herein may be implemented via one or more components, systems, servers, appliances, other subcomponents, or distributed between such elements. When implemented as a system, such systems may include an/or involve, inter alia, components such as software modules, general-purpose CPU, RAM, etc. found in general-purpose computers. In implementations where the innovations reside on a server, such a server may include or involve components such as CPU, RAM, etc., such as those found in general-purpose computers.

Additionally, the system and method herein may be achieved via implementations with disparate or entirely different software, hardware and/or firmware components, beyond that set forth above. With regard to such other components (e.g., software, processing components, etc.) and/or computer-readable media associated with or embodying the present inventions, for example, aspects of the innovations herein may be implemented consistent with numerous general purpose or special purpose computing systems or configurations. Various exemplary computing systems, environments, and/or configurations that may be suitable for use with the innovations herein may include, but are not limited to: software or other components within or embodied on personal computers, servers or server computing devices such as routing/connectivity components, hand-held or laptop devices, multiprocessor systems, microprocessor-based systems, set top boxes, consumer electronic devices, network PCs, other existing computer platforms, distributed computing environments that include one or more of the above systems or devices, etc.

In some instances, aspects of the system and method may be achieved via or performed by logic and/or logic instructions including program modules, executed in association with such components or circuitry, for example. In general, program modules may include routines, programs, objects, components, data structures, etc. that perform particular tasks or implement particular instructions herein. The inventions may also be practiced in the context of distributed software, computer, or circuit settings where circuitry is connected via communication buses, circuitry or links. In distributed settings, control/instructions may occur from both local and remote computer storage media including memory storage devices.

The software, circuitry and components herein may also include and/or utilize one or more types of computer readable media. Computer readable media can be any available media that is resident on, associable with, or can be accessed by such circuits and/or computing components. By way of example, and not limitation, computer readable media may comprise computer storage media and communication media. Computer storage media includes volatile and nonvolatile, removable and non-removable media implemented in any method or technology for storage of information such as computer readable instructions, data structures, program modules or other data. Computer storage media includes, but is not limited to, RAM, ROM, EEPROM, flash memory or other memory technology, CD-ROM, digital versatile disks (DVD) or other optical storage, magnetic tape, magnetic disk storage or other magnetic storage devices, or any other medium which can be used to store the desired information and can accessed by computing component. Communication media may comprise computer readable instructions, data structures, program modules and/or other components. Further, communication media may include wired media such as a wired network or direct-wired connection, however no media of any such type herein includes transitory media. Combinations of any of the above are also included within the scope of computer readable media.

In the present description, the terms component, module, device, etc. may refer to any type of logical or functional software elements, circuits, blocks and/or processes that may be implemented in a variety of ways. For example, the functions of various circuits and/or blocks can be combined with one another into any other number of modules. Each module may even be implemented as a software program stored on a tangible memory (e.g., random access memory, read only memory, CD-ROM memory, hard disk drive, etc.) to be read by a central processing unit to implement the functions of the innovations herein. Or, the modules can comprise programming instructions transmitted to a general purpose computer or to processing/graphics hardware via a transmission carrier wave. Also, the modules can be implemented as hardware logic circuitry implementing the functions encompassed by the innovations herein. Finally, the modules can be implemented using special purpose instructions (SIMD instructions), field programmable logic arrays or any mix thereof which provides the desired level performance and cost.

As disclosed herein, features consistent with the disclosure may be implemented via computer-hardware, software and/or firmware. For example, the systems and methods disclosed herein may be embodied in various forms including, for example, a data processor, such as a computer that also includes a database, digital electronic circuitry, firmware, software, or in combinations of them. Further, while some of the disclosed implementations describe specific hardware components, systems and methods consistent with the innovations herein may be implemented with any combination of hardware, software and/or firmware. Moreover, the above-noted features and other aspects and principles of the innovations herein may be implemented in various environments. Such environments and related applications may be specially constructed for performing the various routines, processes and/or operations according to the invention or they may include a general-purpose computer or computing platform selectively activated or reconfigured by code to provide the necessary functionality. The processes disclosed herein are not inherently related to any particular computer, network, architecture, environment, or other apparatus, and may be implemented by a suitable combination of hardware, software, and/or firmware. For example, various general-purpose machines may be used with programs written in accordance with teachings of the invention, or it may be more convenient to construct a specialized apparatus or system to perform the required methods and techniques.

Aspects of the method and system described herein, such as the logic, may also be implemented as functionality programmed into any of a variety of circuitry, including programmable logic devices (“PLDs”), such as field programmable gate arrays (“FPGAs”), programmable array logic (“PAL”) devices, electrically programmable logic and memory devices and standard cell-based devices, as well as application specific integrated circuits. Some other possibilities for implementing aspects include: memory devices, microcontrollers with memory (such as EEPROM), embedded microprocessors, firmware, software, etc. Furthermore, aspects may be embodied in microprocessors having software-based circuit emulation, discrete logic (sequential and combinatorial), custom devices, fuzzy (neural) logic, quantum devices, and hybrids of any of the above device types. The underlying device technologies may be provided in a variety of component types, e.g., metal-oxide semiconductor field-effect transistor (“MOSFET”) technologies like complementary metal-oxide semiconductor (“CMOS”), bipolar technologies like emitter-coupled logic (“ECL”), polymer technologies (e.g., silicon-conjugated polymer and metal-conjugated polymer-metal structures), mixed analog and digital, and so on.

It should also be noted that the various logic and/or functions disclosed herein may be enabled using any number of combinations of hardware, firmware, and/or as data and/or instructions embodied in various machine-readable or computer-readable media, in terms of their behavioral, register transfer, logic component, and/or other characteristics. Computer-readable media in which such formatted data and/or instructions may be embodied include, but are not limited to, non-volatile storage media in various forms (e.g., optical, magnetic or semiconductor storage media) though again does not include transitory media. Unless the context clearly requires otherwise, throughout the description, the words “comprise,” “comprising,” and the like are to be construed in an inclusive sense as opposed to an exclusive or exhaustive sense; that is to say, in a sense of “including, but not limited to.” Words using the singular or plural number also include the plural or singular number respectively. Additionally, the words “herein,” “hereunder,” “above,” “below,” and words of similar import refer to this application as a whole and not to any particular portions of this application. When the word “or” is used in reference to a list of two or more items, that word covers all of the following interpretations of the word: any of the items in the list, all of the items in the list and any combination of the items in the list.

Although certain presently preferred implementations of the invention have been specifically described herein, it will be apparent to those skilled in the art to which the invention pertains that variations and modifications of the various implementations shown and described herein may be made without departing from the spirit and scope of the invention. Accordingly, it is intended that the invention be limited only to the extent required by the applicable rules of law.

While the foregoing has been with reference to a particular embodiment of the disclosure, it will be appreciated by those skilled in the art that changes in this embodiment may be made without departing from the principles and spirit of the disclosure, the scope of which is defined by the appended claims.

Finally, it is the applicant's intent that only claims that include the express language “means for” or “step for” be interpreted under 35 U.S.C. 112(f). Claims that do not expressly include the phrase “means for” or “step for” are not to be interpreted under 35 U.S.C. 112(f).

What is claimed is:

1. A memory array comprising:
a read bit line (RBL);
a complimentary read bit line (RBLb);
a plurality of storage cells each selectably coupled to the RBL and the RBLb;
a plurality of first coupling circuits, each respective first coupling circuit coupling a respective storage cell of the plurality of storage cells to the RBL such that an XNOR of a read enable (RE) signal and a content of the respective storage cell is output to the RBL in response to the RE signal;
a plurality of second coupling circuits, each respective second coupling circuit coupling a respective storage cell of the plurality of storage cells to the RBLb such that an XOR of the RE signal and the content of the respective storage cell is output to the RBLb in response to the RE signal; and
a sensing circuit coupled to the RBL and the RBLb and configured to compare a signal on the RBL to a signal on the RBLb and output a comparison result.

2. The memory array of claim 1, further comprising a bias coupled to the RBL and the RBLb.

3. The memory array of claim 1, wherein the comparison result represents a multiply-accumulate result of contents of the plurality of storage cells.

4. The memory array of claim 1, wherein each of the plurality of first coupling circuits is configured to pull down the RBLb in response to the XNOR.

5. The memory array of claim 1, wherein each of the plurality of first coupling circuits comprises:
a first switch pair comprising a first switch configured to close in response to the RE signal being high and a second switch configured to close in response to a complimentary data signal from the respective storage cell being high, the first switch pair being arranged to couple RBL to ground by closing the first switch and the second switch; and
a second switch pair comprising a third switch configured to close in response to a complimentary RE signal being high and a fourth switch configured to close in response to a data signal from the respective storage cell being high, the second switch pair being arranged to couple RBL to ground by closing the third switch and the fourth switch.

6. The memory array of claim 5, wherein:
the first switch selectably couples the respective storage cell to the second switch;
the second switch selectably couples RBL to ground;
the third switch selectably couples the respective storage cell to the fourth switch; and
the fourth switch selectably couples RBL to ground.

7. The memory array of claim 1, wherein each of the plurality of second coupling circuits is configured to pull down the RBL in response to the XOR.

8. The memory array of claim 1, wherein each of the plurality of second coupling circuits comprises:
a third switch pair comprising a fifth switch configured to close in response to the RE signal being high and a sixth switch configured to close in response to a data signal from the respective storage cell being high, the third switch pair being arranged to couple RBLb to ground by closing the fifth switch and the sixth switch; and
a fourth switch pair comprising a seventh switch configured to close in response to a complimentary RE signal being high and an eighth switch configured to close in response to a complimentary data signal from the respective storage cell being high, the fourth switch pair being arranged to couple RBLb to ground by closing the seventh switch and the eighth switch.

9. The memory array of claim 8, wherein:
the fifth switch selectably couples the respective storage cell to the sixth switch;
the sixth switch selectably couples RBLb to ground;
the seventh switch selectably couples the respective storage cell to the eighth switch; and
the eighth switch selectably couples RBLb to ground.

10. A memory array comprising:
a read bit line (RBL);
a complimentary read bit line (RBLb);
a plurality of storage cells each selectably coupled to the RBL and the RBLb such that an XNOR of a read enable (RE) signal and a content of the respective storage cell is output to the RBL in response to the RE signal and an XOR of the RE signal and the content of the respective storage cell is output to the RBLb in response to the RE signal; and
a sensing circuit coupled to the RBL and the RBLb and configured to compare a signal on the RBL to a signal on the RBLb and output a comparison result.

11. The memory array of claim 10, further comprising a bias coupled to the RBL and the RBLb.

12. The memory array of claim 10, wherein the comparison result represents a multiply-accumulate result of contents of the plurality of storage cells.

13. The memory array of claim 10, further comprising a plurality of first coupling circuits coupled to respective ones of the plurality of storage cells, each of the plurality of first coupling circuits being configured to pull down the RBL in response to the XOR of the respective one of the plurality of storage cells.

14. The memory array of claim 10, further comprising a plurality of second coupling circuits coupled to respective ones of the plurality of storage cells, each of the plurality of second coupling circuits being configured to pull down the RBLb in response to the XNOR of the respective one of the plurality of storage cells.

15. A method comprising:
supplying a read enable signal to a memory array comprising a plurality of storage cells each selectively coupled to a read bit line (RBL) and a complimentary read bit line (RBLb);
in response to the read enable signal, outputting, by each respective storage cell, a respective XNOR of the read enable signal and a respective content of the respective storage cell to the RBL, thereby forming an RBL signal;
in response to the read enable signal, outputting, by each respective storage cell, a respective XOR of the read enable signal and a respective content of the respective storage cell to the RBLb, thereby forming an RBLb signal;
sensing, by a sensing circuit, the RBL signal on the RBL and the RBLb signal on the RBLb;
comparing, by the sensing circuit, the RBL signal and the RBLb signal; and
outputting a result of the comparing.

16. The method of claim 15, further comprising supplying a bias to the RBL and the RBLb.

17. The method of claim 15, wherein the result of the comparing represents a multiply-accumulate result of contents of the plurality of storage cells.

18. The method of claim 15, wherein the outputting the respective XNOR comprises pulling down the RBLb in response to the respective XNOR.

19. The method of claim 15, wherein the outputting the respective XOR comprises pulling down the RBL in response to the respective XOR.

20. A memory computation cell comprising:
a storage cell configured to store data (D) and complementary data (Db);
a read word line (RE);
a complementary read word line (REb);
a read bit line (RBL) coupled to at least two of D, Db, RE, and REb, the RBL configured to output an XNOR function between RE and D.

21. The memory computation cell of claim 20, further comprising a complementary read bit line (RBLb) coupled to at least two of D, Db, RE, and REb, the RBLb configured to output an XOR function between RE and D.

22. The memory computation cell of claim 20, wherein the RBL is coupled by a first coupling circuit comprising:
a first switch pair comprising a first switch configured to close in response to RE being high and a second switch configured to close in response to REb being high, the first switch pair being arranged to couple RBL to ground by closing the first switch or the second switch; and
a second switch pair comprising a third switch configured to close in response to REb being high and a fourth switch configured to close in response to RE being high, the second switch pair being arranged to couple RBLb to ground by closing the third switch or the fourth switch.

23. The memory computation cell of claim 22, wherein:
the first switch pair selectably couples the storage cell to a switch that selectably couples RBL to ground;
the second switch pair selectably couples the storage cell to a switch that couples RBLb to ground.

24. The memory computation cell of claim 20, wherein the RBL is coupled by a second coupling circuit comprising:
a third switch pair comprising a fifth switch configured to close in response to RE being high and a sixth switch configured to close in response to D being high, the third switch pair being arranged to couple RBLb to ground by closing the fifth switch and the sixth switch; and
a fourth switch pair comprising a seventh switch configured to close in response to REb being high and an eighth switch configured to close in response to Db being high, the fourth switch pair being arranged to couple RBLb to ground by closing the seventh switch and the eighth switch.

25. The memory computation cell of claim 24, wherein:
the fifth switch selectably couples the storage cell to the sixth switch;
the sixth switch selectably couples RBLb to ground;
the seventh switch selectably couples the storage cell to the eighth switch; and
the eighth switch selectably couples RBLb to ground.
